(19) United States
(12) Patent Application Publication
(10) Pub. No.: US 2003/0235995 A1
(43) Pub. Date: Dec. 25, 2003

(54) Method of increasing selectivity to mask when etching tungsten or tungsten nitride

(76) Inventors: Hakeem M. Oluseyi, Richmond, CA (US); Padmapani C. Nallan, San Jose, CA (US)

Correspondence Address: APPLIED MATERIALS, INC., PATENT COUNSEL, Legal Affairs Department, P.O. Box 450A, Santa Clara, CA, 95052, US

(21) Appl. No.: 10/177,890

(22) Filed: Jun. 21, 2002

(51) Int. Cl. H01L 21/302; H01L 21/461

(52) U.S. Cl. 438/710

(57) ABSTRACT

Tungsten is etched with increased selectivity with respect to the etch rate of the mask material. Plasma exposure using a mixture of Cl₂ and O₂ is used, prior to main etch to establish a passivation layer over the mask. A single Cl₂/O₂ exposure may be sufficient to provide the desired selectivity through main etch. As an alternative, main etch is performed incrementally by alternating etch chemistry exposures with plural Cl₂/O₂ exposures to provide a desired main etch selectivity. This method of etching tungsten or tungsten nitride in semiconductor structures is useful, particularly for the etching of gate electrodes that require precise control over the etching process.

### INTRODUCTION

The present invention pertains to a method of etching tungsten or tungsten nitride electrode gates in semiconductor structures. In particular, one etch chemistry is used in repeated alternation with a second etch chemistry to carry out the majority of the etching process, i.e., the main etch.

### BACKGROUND OF THE INVENTION

Semiconductor devices as a whole typically include self-aligned contact structures and gate electrodes that are fabricated from multiple film layers of differing compositions. Tungsten nitride films have previously been used as barrier layers, and tungsten has been used as a conductor in various semiconductor device structures. Recently, both tungsten and tungsten nitride have been developing as gate materials, as a result of smaller device geometries.

In many instances, the tungsten or tungsten nitride film (layer) is deposited over a thin (less than about 50 Å thick) silicon oxide inorganic dielectric layer. During patterned etching of the multiple film layer structure, it is desired to plasma dry etch through the tungsten or tungsten nitride layer and to stop etching at the surface of the silicon oxide layer. This makes it important that the etch selectivity for etching, of tungsten or tungsten nitride (in preference over silicon. oxide) be high. The term “selectivity” typically refers to a ratio of etch rates of two materials.

Smaller device geometries provide a profile that permits placement of more devices over a given surface area. More importantly, though, the smaller device geometries make the devices operate faster. As the device geometries become smaller, etching of layers of material must be more precise. In the case of a tungsten gate, for example, the gate may be in the form of a thin line or pad and the cross-sectional profile of the etched gate feature is preferably one where the sidewalls of the etched feature are essentially perpendicular to an underlying silicon oxide substrate layer. This means the tungsten must be completely etched to the surface of the silicon oxide substrate layer, leaving no residual “feet” at the bottom of the etched tungsten sidewall. Control of the etch process is critical in providing proper etched tungsten feature profile while avoiding etching away critical thickness of the underlying silicon oxide film substrate.

A dry etching method has been proposed wherein a multilayer film is etched with differing etch chemistries for the different layers of the film. The first layer of multilayer film is one selected from tungsten, molybdenum, and a silicide thereof. Underlying the first layer is a second layer of polycrystal silicon, which overlies a silicon oxide insulation film. The etching step for the first layer uses a plasma etchant source gas made up of a first gas selected from fluorine, sulfur hexafluoride, and nitrogen trifluoride, or a mixture gas containing the first gas and a second gas selected from hydrogen chloride, hydrogen bromide, chlorine, bromine, and carbon tetrachloride. Etching of the second layer of polycrystalline silicon is carried out using a plasma etchant source gas made up of the second gas and a third gas selected from an inert gas, nitrogen gas, oxygen gas, silicon tetrachloride gas and carbon monoxide gas. In the second etch step, the amount of the third gas added to the second gas should preferably be in the range between 0 and 10 volume % of the total etching gas mixture. For further details, refer to U.S. Pat. No. 5,259,923 issued to Hori et al.

It has also been proposed to fabricate a silicon based MOS transistor having an inverse-T refractory metal gate structure. The gate fabricated according to the proposed method comprises a main tungsten portion deposited via chemical vapor deposition (CVD) and a lower sputtered tungsten portion (deposited via sputtering) that outwardly extends from the bottom of the CVD portion. A Cl₂/O₂ plasma etch is used to etch the CVD tungsten layer and a chemical etch (KH₂PO₄/KOH/K₃Fe(CN)₆) is used to etch the sputtered tungsten portion. The sputtered tungsten layer is said to act as a shield to protect the underlying gate oxide layer from ion damage throughout the fabrication process. In particular, the sputtered tungsten is said to be more resistant to Cl₂/O₂ reactive ion etch than is CVD tungsten. For further details, refer to U.S. Pat. No. 5,599,725 issued to Dorleans et al.

It has been further proposed to fabricate sidewall spacers for a self-aligned contact hole by deposition of a metal such as tungsten which is RIE etched using a conventional etchback procedure, without the use of a photoresist masking, using, a Cl₂/SF₆/BCl₃/Ar etchant gas mixture for plasma generation. For further details, refer to U.S. Pat. No. 6,033,962 to Jeng et al.

These proposed etching processes do not address the problem of how to etch W and/or WN so as to be highly selective with respect to the etch mask. By increasing the selectivity of etch with respect to the mask, the mask material can be made thinner. Without a need to deposit thick mask material to be consumed by a poorly selective etch process, overall process time may be decreased thereby increasing throughput.

One proposal for highly selective etch of silicon utilizes alternating deposition and etch steps to iteratively drill down through silicon with high selectivity to a photoresist mask. One example of this process would employ a deposition phase where the wafer is exposed to C₄F₈ for 5 seconds, alternated with an etch phase where the wafer is exposed to SF₆ for 10 seconds. The deposition phase and etch phase are repeated alternately several times to gradually etch down through the silicon without etching the photoresist etch mask. Although this silicon etch process is interesting because of its iterative approach, the chemistries employed are quite useless for etching of tungsten.

Thus, what is needed is an etch process that etches W and/or WN with a high selectivity with respect to the etch mask.

### SUMMARY OF THE INVENTION

The present invention relates to a method of etching tungsten or tungsten nitride in semiconductor structures, and particularly to the etching, of gate electrodes that require precise control over the etching process. A method of etching tungsten or tungsten nitride has been discovered that permits precise etch profile control while providing excellent selectivity in favor of etching tungsten (or tungsten nitride) rather than the etch mask (either photoresist mask or hard mask). The etch chemistry also has excellent selectivity in favor of etching W or WN rather than the underlying oxide (typically selected from silicon oxide, silicon oxynitride, tantalum oxide, zirconium oxide, and combinations thereof). The method appears to be applicable to tungsten or tungsten nitride, whether deposited by physical vapor deposition (PVD) or chemical vapor deposition (CVD).

One aspect of the present invention is the ability to etch W and/or WN with a high selectivity with respect to the etch mask.

Another aspect of the present invention is the ability etch W and/or WN with an etch profile that has vertical walls.

Additional aspects and advantages of the present invention will be apparent in the following detailed description read in conjunction with the accompanying drawing figures.

### BRIEF DESCRIPTION OF THE DRAWINGS

FIG. 1 illustrates a schematic cross sectional view of a gate structure prior to the beginning of etch.

FIG. 2 illustrates a schematic cross sectional view of a gate structure after an initial Cl₂/O₂ etch step according to either of first or second embodiments of the present invention.

FIG. 3 illustrates a schematic cross sectional view of the gate structure of FIG. 2 after a main etch step using a second chemistry according to the first embodiment of the present invention.

FIG. 4 illustrates a schematic cross sectional view of the gate structure of FIG. 3 after an over etch step has been executed.

FIG. 5 illustrates a schematic cross sectional view of the gate structure of FIG. 2 after a first partial main etch step using a second chemistry according to the second embodiment of the present invention.

FIG. 6 illustrates a schematic cross sectional view of the gate structure after a second Cl₂/O₂ etch step according to the second embodiments of the present invention.

FIG. 7 illustrates a schematic cross sectional view of the gate structure of FIG. 6 after a second partial main etch step using a second chemistry according to the second embodiment of the present invention.

FIG. 8 illustrates a schematic cross sectional view of the gate structure after a third Cl₂/O₂ etch step according to the second embodiments of the present invention.

FIG. 9 illustrates a schematic cross sectional view of the gate structure of FIG. 8 after a third partial main etch step using a second chemistry according to the second embodiment of the present invention.

### DETAILED DESCRIPTION OF THE VARIOUS EMBODIMENTS

The present invention is directed to the exposure of an etch mask (photoresist or hard mask) patterned onto tungsten (or a tungsten containing material such as tungsten nitride) to a Cl₂/O₂ plasma for a short duration (approx. 5 seconds). During this brief exposure, a passivation layer of WCl₂ is deposited on the etch mask. This passivation layer will slow the etch rate of the mask, but it will not slow the etch rate of the tungsten film. The duration of the Cl₂/O₂ plasma exposure is selected so as to be sufficient to slow the mask etch rate but to ensure that the deposited WCl₂ is thin enough to prevent critical dimension (CD) gain.

According a first embodiment of the present invention, the passivation layer is initially deposited on the mask (using Cl₂/O₂ plasma exposure) and then etching with a second chemistry is then employed to finish the main etch. The passivation layer applied by the initial Cl₂/O₂ exposure is sufficient to provide a high selectivity of etch with respect to the mask during the main etch.

According to a second embodiment of the present invention, the passivation layer is initially deposited on the mask (using Cl₂/O₂ plasma exposure) and then etching with a second chemistry is alternated iteratively with deposition of a passivation layer on the mask using Cl₂/O₂ plasma exposure. This repeated alternation of two chemistries is alternated until the entire film is almost gone.

For each of these embodiments, the second chemistry is not limited to any particular choice of chemistry. The use of fluorine-based chemistries has been found to be useful as the second chemistry, for example SF₆/N₂ has been used with good success.

The final portion of the W etch at the interface between the W film and the underlying gate oxide layer is handled by an over etch step. One option for performing the over etch is to use a Cl₂/O₂ chemistry. However, other over etch chemistries are also useful to finish etching all the way to the upper surface of the gate oxide layer.

The embodiments of the present invention employ a similar chemistry to that disclosed in co-pending application Ser. No. 09/614,396, filed Jul. 12, 2000, by the same inventors as of the present application. The invention described in the co-pending application is directed to a process of over etching (OE) tungsten that has very good selectivity with respect to the underlying gate oxide layer. In contrast, the present invention is useful for increasing selectivity of main etch (ME) of tungsten with respect to the patterned etch mask.

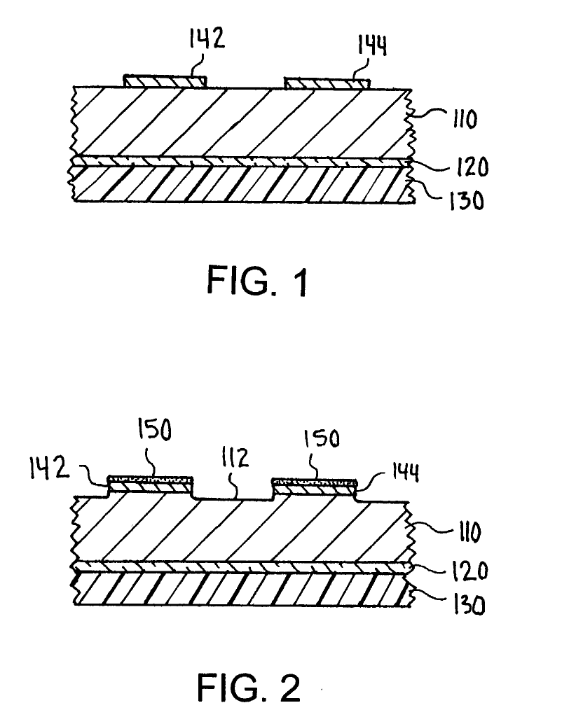

Referring to FIG. 1, a schematic cross sectional view of a gate structure prior to the beginning of etch is illustrated. A tungsten film 110 is deposited broadly over the drain, gate, and source regions of a transistor. A thin layer of gate oxide 120 (typically SiO₂) is sandwiched between the tungsten film 110 and an underlying silicon substrate 130. Etch mask features 142, 144 (typically Si₃N₄) are patterned onto the tungsten film 110 to define where tungsten features will be formed by etching.

Referring to FIG. 2, a schematic cross sectional view is illustrated of a gate structure after an initial Cl₂/O₂ etch step. This initial step is practiced according to either of the two embodiments of the present invention being described. The initial Cl₂/O₂ etch is effective to etch away an unmasked portion 112 of the tungsten film 110 and deposit a passivation layer 150 of WCl₂ on the etch mask 142, 144. As the Cl₂/O₂ plasma reacts with the exposed W, two primary reaction products are formed: WClO and WCl₂. The WClO is very volatile and is easily evacuated from the surface of the workpiece via a vacuum system. Some portion of the WCl₂ molecules deposit as a passivation layer 150 on the etch mask 142, 144.

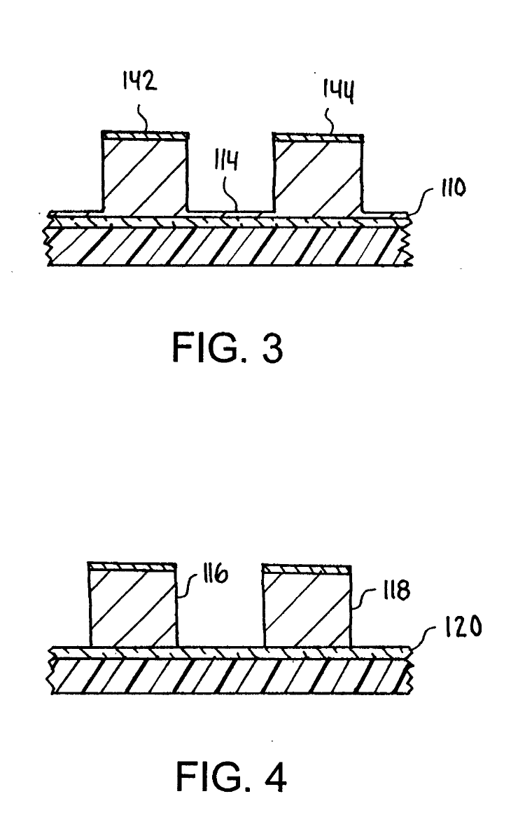

Referring to FIG. 3, a schematic cross sectional view is illustrated of the gate structure of FIG. 2 after a main etch step using a second chemistry according to the first embodiment of the present invention. The main etch is carried out in a single step following the pre-etch exposure to Cl₂/O₂ to form a passivation layer. The main etch eats away almost all of the unmasked portion 114 of the tungsten film 110, as well as the passivation layer and some portion of the etch mask 142, 144. Fluorine and fluoride gasses are examples of chemistries appropriate for the main etch according to the first embodiment.

Referring to FIG. 4, a schematic cross sectional view is illustrated of the gate structure of FIG. 3 after an over etch step has been executed. The over etch is carried out according to any of several known methods as are understood in the art. The over etch is not an aspect of the present invention and is illustrated merely for sake of clarity and completeness. This view shows what the etched W features 116, 118 look like when the etching is completed, with the gate oxide 120 entirely exposed in between.

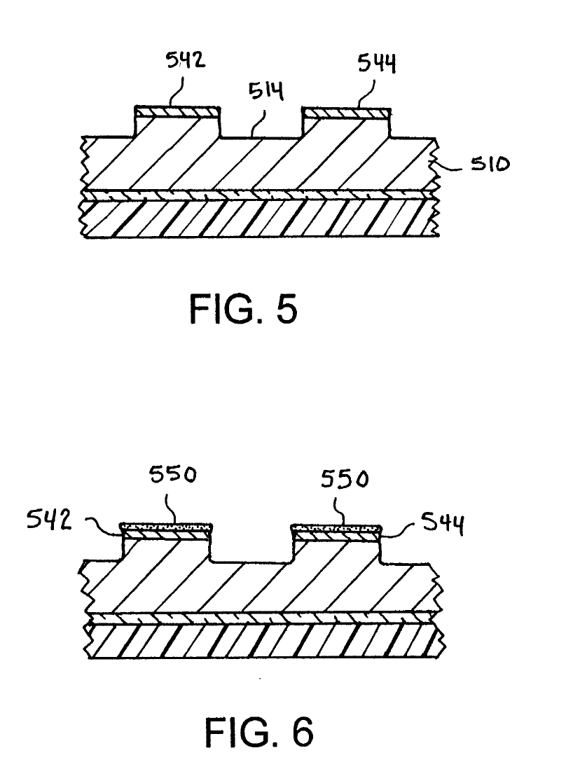

Referring to FIG. 5, a schematic cross sectional view is illustrated of the gate structure of FIG. 2 after a first partial main etch step using a second chemistry according to the second embodiment of the present invention. According to the second embodiment, the main etch is conducted iteratively with multiple cycles of etching of tungsten alternated with deposition of a passivation layer on the etch mask to slow the etch rate of the mask. Following the pre-etch exposure to Cl₂/O₂ to form a passivation layer (as shown in FIG. 2), a partial main etch (using a second chemistry) eats away a fraction of the unmasked portion 514 of the tungsten film 510, as well as the passivation layer and some portion of the etch mask 542, 544. Fluorine and fluoride gasses are examples of chemistries appropriate for use as the second chemistry for the main etch.

Referring to FIG. 6, a schematic cross sectional view is illustrated of the gate structure after a second Cl₂/O₂ etch step according to the second embodiments of the present invention. This repeated exposure to Cl₂/O₂ provides a renewed layer of passivating WCl₂ 550 to increase the selectivity of etch with respect to the etch mask 542, 544.

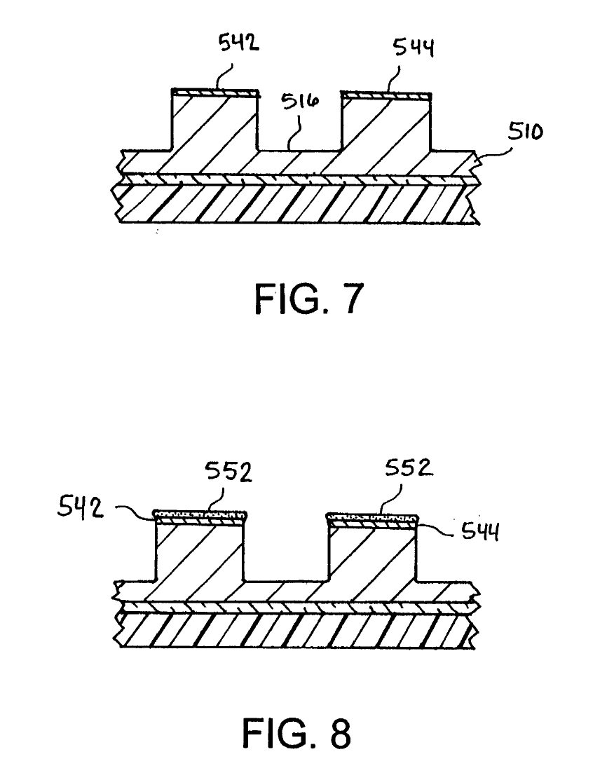

Referring to FIG. 7, a schematic cross sectional view is illustrated of the gate structure of FIG. 6 after a second partial main etch step using a second chemistry according to the second embodiment of the present invention. This repeated partial main etch (using the second chemistry) eats away a fraction of the unmasked portion 516 of the tungsten film 510, as well as the passivation layer and some portion of the etch mask 542, 544.

Referring to FIG. 8, a schematic cross sectional view is illustrated of the gate structure after a third Cl₂/O₂ etch step according to the second embodiments of the present invention. This further repeated exposure to Cl₂/O₂ provides a renewed layer of passivating WCl₂ 552 to again increase the selectivity of etch with respect to the etch mask 542, 544.

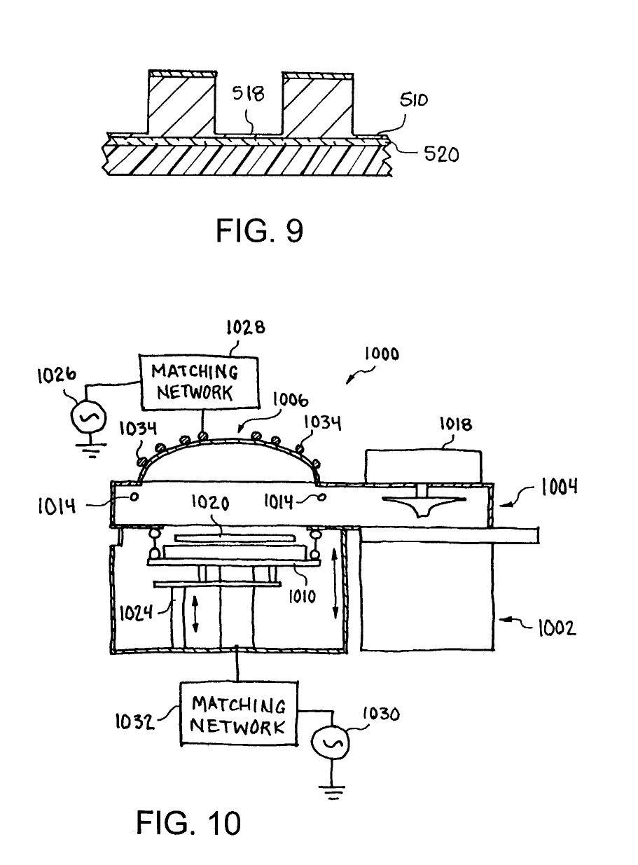

Referring to FIG. 9, a schematic cross sectional view is illustrated of the gate structure of FIG. 8 after a third partial main etch step using a second chemistry according to the second embodiment of the present invention. This final, repeated partial main etch (again using the second chemistry) eats away a fraction of the unmasked portion 518 of the tungsten film 510 just short of the underlying oxide layer 520.

This example of a process according to the second embodiment (as shown collectively in FIGS. 2 and 5-9) shows three iterations of the passivate/etch cycle to complete a main etch operation. The exact number of cycles used is not a critical aspect of the invention and is varied according to a trade off of minimizing process time (to increase throughput), increasing etch selectivity with respect to the mask, and providing vertical walls for the etched tungsten features that are as nearly 90 degrees as possible. Process time would be kept to a minimum by having only one passivate/etch cycle (i.e., the first embodiment, discussed above). The repetition of cycles is useful to increase selectivity of etch with respect to the mask by repetitively depositing and consuming a protective passivation layer on the mask. The faster the rate of etch of the passivation layer compared to the rate of etch of tungsten for the second chemistry, the more times the cycle will need to be repeated.

Referring to FIG. 10, the etch processes embodiments described herein may be successfully carried out in a CENTURA™ Integrated Processing System as illustrated, available from Applied Materials, Inc. of Santa Clara, Calif. The system is shown and described in U.S. Pat. No. 5,186,718, the disclosure of which is hereby incorporated by reference. Although the etch process embodiments described herein have been implemented using a chamber such as that shown in FIG. 10, any of the etch processors available in the industry should be able to take advantage of the etch chemistry described herein, with some adjustment to certain process parameters. The equipment shown in schematic in FIG. 10 includes a Decoupled Plasma Source (DPS) of the kind described by Yan Ye et al. at the Proceedings of the Eleventh International Symposium of Plasma Processing, May 7, 1996 and as published in the Electrochemical Society Proceedings, Volume 96-12, pp. 222-233 (1996). The plasma processing chamber enables the processing of an 8 inch (200 mm) diameter wafer. Of course, the present invention is not limited to wafer size and may be used on wafers of any size.

FIG. 10 shows a schematic of a side view of an individual CENTURA® etch chamber 1000. The etch chamber 1000 consists of an upper chamber 1004 having a ceramic dome 1006, and a lower chamber 1008. The lower chamber 1008 includes a monopolar electrostatic chuck (ESC) cathode 1010. Gas is introduced into the chamber via gas injection nozzles 1014 for uniform gas distribution. Chamber pressure is controlled by a closed-loop pressure control system (not shown) using a throttle valve 1018 in the path to the vacuum pump 1002. During processing, a substrate 1020 is introduced into the lower chamber 1008 through inlet 1022. The substrate 1020 is held in place by means of a static charge generated on the surface of electrostatic chuck (ESC) cathode 1010 by applying a DC voltage to a conductive layer (not shown) located under a dielectric film (not shown) on the chuck surface. The cathode 1010 and substrate 1020 are then raised by means of a wafer lift 1024 and sealed against the upper chamber 1004 in position for processing. Etch gases are introduced into the upper chamber 1004 via gas injection nozzles 1014. The etch chamber 1000 uses an inductively coupled plasma source power 1026 and matching network 1028 operating at 12.56 MHz for generating and sustaining a high density plasma. The wafer is biased with an RF source 1030 and matching network 1032 operating at 13.56 MHz. Separate controllers (not shown) control the plasma source power 1026 and substrate biasing means 1030.

In test runs practicing the present invention we have been able to improve over the prior art selectivity value of 2:1 to a 10:1 selectivity, a factor of five improvement. The walls of the etched features have been near vertical to vertical with the angles of the walls with respect to the underlying substrate being in the range of 88-90 degrees.

The present invention has been described in terms of preferred embodiments, however, it will be appreciated that various modifications and improvements may be made to the described embodiments, without departing from the scope of the invention.

What is claimed is:

1. A method of etching a tungsten-containing layer on a semiconductor workpiece, the tungsten-containing layer being partially covered by an etch mask, the method comprising:
initially exposing the workpiece to a plasma formed from a first chemistry that contains a mixture of Cl₂ and O₂, so as to form a passivation layer on the etch mask; and
subsequently exposing the workpiece to a plasma formed from a second chemistry, different from the first chemistry, to etch the tungsten-containing layer;
wherein the passivation layer formed by the initial Cl₂/O₂ exposure causes the tungsten-containing layer to be etched with a high selectivity with respect to the etch mask.

2. The method of etching a tungsten-containing layer of claim 1, wherein the tungsten-containing layer is formed of substantially pure tungsten.

3. The method of etching a tungsten-containing layer of claim 1, wherein the tungsten-containing layer is formed of tungsten nitride.

4. The method of etching a tungsten-containing layer of claim 1, wherein the tungsten-containing layer comprises the combination a layer of tungsten nitride and a layer of substantially pure tungsten.

5. The method of etching a tungsten-containing layer of claim 1, wherein the first chemistry consists essentially of Cl₂ and O₂.

6. A method of etching a tungsten-containing layer on a semiconductor workpiece, the tungsten-containing layer being partially covered by an etch mask, the method comprising:
first exposing the workpiece to a plasma formed from a first chemistry that contains a mixture of Cl₂ and O₂, so as to form a passivation layer on the etch mask;
secondly exposing the workpiece to a plasma formed from a second chemistry, different from the first chemistry, to etch the tungsten-containing layer; and
repeating the first exposing and the secondly exposing one or more times in sequence to iteratively perform a main etch of the tungsten-containing layer;
wherein the passivation layer formed by the repeated Cl₂/O₂ exposures causes the tungsten-containing layer to be etched with a high selectivity with respect to the etch mask.

7. The method of etching a tungsten-containing layer of claim 6, wherein the tungsten-containing layer is formed of substantially pure tungsten.

8. The method of etching a tungsten-containing layer of claim 6, wherein the tungsten-containing layer is formed of tungsten nitride.

9. The method of etching a tungsten-containing layer of claim 6, wherein the tungsten-containing layer comprises the combination a layer of tungsten nitride and a layer of substantially pure tungsten.

10. The method of etching a tungsten-containing layer of claim 6, wherein the first chemistry consists essentially of Cl₂ and O₂.
